(19) United States
(12) Patent Application Publication
(10) Pub. No.: US 2008/0000876 A1
(43) Pub. Date: Jan. 3, 2008

(54) Plasma etching apparatus and plasma etching method using the same

(75) Inventors: Sang-Soo Park, Kyoungki-do (KR); Hyun-Suk Sung, Kyoungki-do (KR); Dong-Goo Choi, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/648,026

(22) Filed: Dec. 28, 2006

(30) Foreign Application Priority Data
Jun. 29, 2006 (KR) 2006-0059320

(51) Int. Cl. C23F 1/00; H01L 21/306; H01L 21/302

(52) U.S. Cl. 216/67; 438/689; 156/915; 156/345.51

(57) ABSTRACT

A plasma etching apparatus includes a plasma processing chamber, an electro static chuck installed in the plasma processing chamber and providing a region where a wafer is to be placed, and a focus ring surrounding an edge of the wafer at an edge portion of the electro static chuck and including: a first region surrounding the edge of the wafer; and a second region disposed under a bottom surface of the wafer. The first region has a surface disposed higher than that of the wafer.

### CROSS-REFERENCE TO RELATED APPLICATIONS

The present invention claims priority of Korean patent application number(s) 10-2006-0059320, filed on Jun. 29, 2006, which is incorporated by reference in its entirety.

### BACKGROUND OF THE INVENTION

The present invention relates to a method for fabricating a semiconductor device; and more particularly, to a method for preventing a contact hole of a semiconductor device from tilting.

In a storage node process of a semiconductor device, as semiconductor devices have become more highly integrated, an area in which a storage node is overlapped with a storage node contact plug has decreased. Accordingly, a small hole may tilt and as a result, a single bit fail when the storage node and the storage node contact plug are not in contact with each other may occur.

FIG. 1 illustrates an internal structure of a typical plasma etching apparatus. A wafer 12 where a contact hole is to be formed is disposed over an upper portion of an electro static chuck 11. A focus ring 13 is disposed to surround an edge of the wafer 12 in an edge portion of the electro static chuck 11. The focus ring 13 may include silicon, and serves a role in focusing plasma on the wafer 12.

Etching is performed to form the contact hole in a situation which the wafer 12 moves over the electro static chuck 11 inside a typical etching chamber shown in FIG. 1. As etching is performed, the focus ring 13 disposed in the edge portion of the electro static chuck 11 may be subjected to abrasion by etch ions.

Accordingly, in a situation which a sheath region between the wafer 12 and plasma, i.e., a height T1 between the etch ions and the wafer 12, is maintained, a height T2 between a surface of the focus ring 13 and the etch ions is changed to a height T3 due to the abrasion of the focus ring 13. That is, the height between the surface of the focus ring 13 and the etch ions is lowered down the wafer 12 due to the abrasion of the focus ring 13.

If the height T2 is changed to the height T3, a plasma sheath may change, and as the change in the height T2 increases, the angle α of incidence of the etch ions to the wafer 12 may become greatly changed. A movement of the etch ions is accelerated by a sheath potential to perform etching. This sheath potential is referred to as the plasma sheath.

For instance, when using a half D2 of a section D1 where the focus ring 13 is used, the plasma sheath is formed at an inner portion of the edge of the wafer 12. As a result, a tilting phenomenon may be generated at the edge of the wafer 12, thereby incurring a single bit fail as shown in FIG. 2.

Since polymers generated at a portion between a bottom portion of the wafer 12 and the focus ring 13, the edge of the wafer 12, and the focus ring 13 is carbon-based polymers, electric charges are charged to the polymers. Accordingly, an electromotive force may be produced, thereby changing the plasma sheath.

FIG. 2 illustrates a tilting phenomenon of a typical storage node contact hole. The tilting phenomenon may be generated mainly at an edge of a wafer according to constitution of the typical etching apparatus. The tilting phenomenon may be generated due to abrasion of a focus ring disposed in the edge of the wafer and polymers generated during etching.

FIG. 3A illustrates a typically observed limitation due to a storage node contact hole not contacting a storage node contact plug. FIG. 3B illustrates a normal case that a storage node contact hole contacts a storage node contact plug. Unlike the normal case shown in FIG. 3B, a mis-alignment occurs between the storage node contact plug SNC PLUG and the storage node hole SN HOLE in FIG. 3A. This limitation illustrated in FIG. 3A may occur due to a tilting phenomenon.

### SUMMARY OF THE INVENTION

Embodiments of the present invention are directed to provide a plasma etching apparatus and a plasma etching method using the same, wherein the plasma etching apparatus prevents an occurrence of tilting phenomenon due to abrasion of a focus ring and polymers generated during etching.

In accordance with an aspect of the present invention, there is provided a plasma etching apparatus including: a plasma processing chamber; an electro static chuck installed in the plasma processing chamber and providing a region where a wafer is to be placed; and a focus ring surrounding an edge of the wafer at an edge portion of the electro static chuck and including: a first region surrounding the edge of the wafer; and a second region disposed under a bottom surface of the wafer, wherein the first region has a surface disposed higher than that of the wafer.

In accordance with another aspect of the present invention, there is provided a plasma etching method, including: moving a wafer where a target layer is formed to the inside of a chamber of a plasma etching apparatus comprising a focus ring; etching the target layer inside the chamber to form a pattern; and performing a post etch treatment on the wafer and the focus ring.

### BRIEF DESCRIPTION OF THE DRAWINGS

FIG. 1 illustrates an internal structure of a typical plasma etching apparatus;

FIG. 2 illustrates a typical tilting phenomenon of a storage node contact hole;

FIG. 3A illustrates a typically observed limitation due to the fact that a storage node contact hole does not contact a storage node contact plug;

FIG. 3B illustrates a normal case that a storage node contact hole contacts a storage node contact plug; and

FIG. 4 illustrates an internal structure of a plasma etching apparatus in accordance with an embodiment of the present invention.

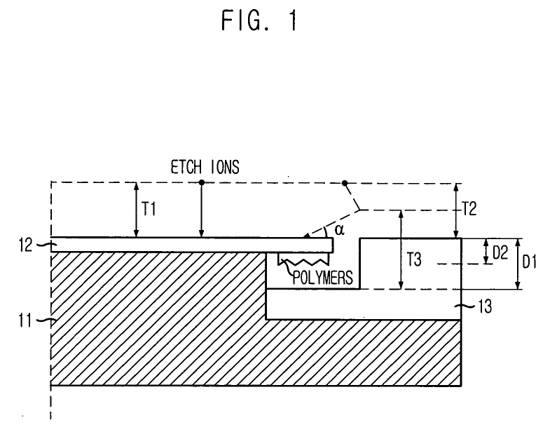

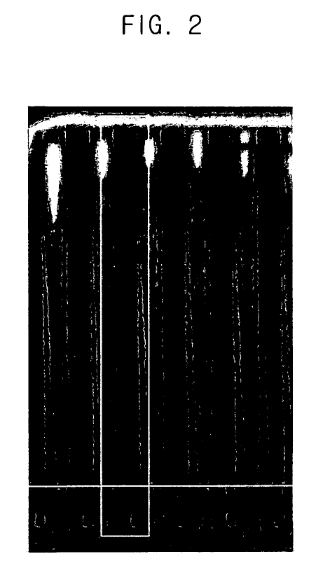

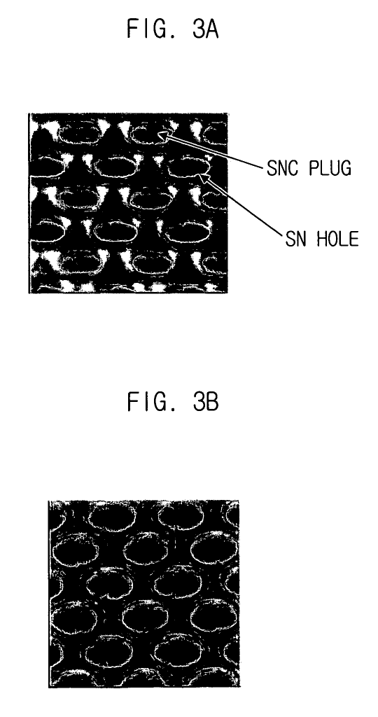

### DESCRIPTION OF SPECIFIC EMBODIMENTS

The embodiment of the present invention which will be explained relates to control abrasion on a focus ring and generation of polymers which cause a hole to tilt. Accordingly, the focus ring is optimized to reduce a change in a plasma sheath, and the polymers are removed performing a post etch treatment. As a result, a tilting phenomenon can be prevented.

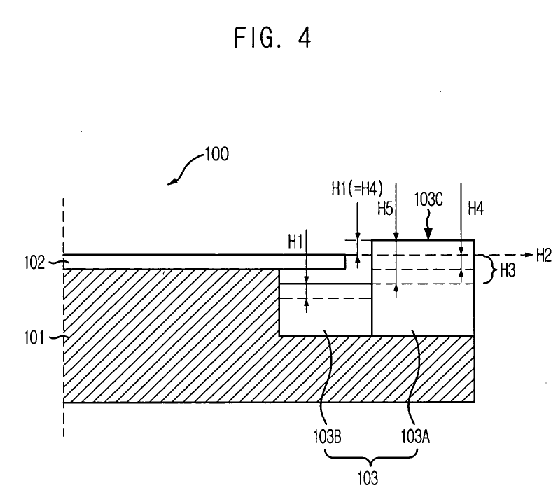

FIG. 4 illustrates an internal structure of a plasma etching apparatus in accordance with an embodiment of the present invention. The plasma etching apparatus includes a plasma processing chamber 100 having a certain volume, an electro static chuck 101, and a focus ring 103. The electro static chuck 101 is included in the plasma processing chamber 100, and a wafer 102 in which etching is to be performed is disposed on the electro static chuck 101. The focus ring 103 is disposed in an edge portion of the electro static chuck 101 to surround an edge of the wafer 102. A surface 103C of the focus ring 103 surrounding the edge of the wafer 102 is positioned at a portion with a height greater than the height of a surface of the wafer 102.

The focus ring 103 includes a first region 103A surrounding the edge of the wafer 102, and a second region 103B disposed under the edge of the wafer 102. In more detail, the surface 103C of the focus ring 103 surrounding the edge of the wafer 102 is the same as a surface of the first region 103A. The surface 103C of the first region 103A is disposed higher than the surface of the wafer 102 by a height H1.

If comparing the focus ring 103 according to the embodiment of the present invention to the typical focus ring, a surface of the typical focus ring surrounding an edge of a wafer is disposed at a portion with the height H2 substantially the same as that of a surface of the wafer. However, in this embodiment of the present invention, the surface 103C of the focus ring 103 surrounding the edge of the wafer 102 is disposed higher than the surface of the wafer 102 by the height H1. In more detail, the surface 103C of the focus ring 103 is positioned higher than the surface of the wafer 102 by extending upward a height H4 corresponding to half of the section H3 where the typical focus ring is used (i.e., an abrasion thickness to be used without replacement of the typical focus ring) from the surface of the wafer 102. For instance, assuming that the section H3 where the typical focus ring is used has a thickness ranging from about 0 mm to about 5 mm, the surface 103C of the focus ring 103 in this embodiment of the present invention is disposed higher than the surface of the typical focus ring as much as a thickness of about 0.25 mm corresponding to the height H4. The height H1 extending upward from the surface of the wafer 102 to dispose the surface 103C of the focus ring 103 higher than the surface of the wafer 102 is substantially the same as the height H4 corresponding to half of the section H3 where the typical focus ring is used.

In this embodiment of the present invention, a section H5 where the focus ring 103 is used has a range (i.e., a thickness ranging from about 0 mm to about 0.75 mm) greater than the maximum range (e.g., a thickness of about 5 mm) of the section H3 where the typical focus ring is used by a thickness of about 0.25 mm. The section H5 where the focus ring 103 is used has a more space than the section H3 where the typical focus ring is used as much as the thickness of about 0.25 mm.

While the abrasion thickness to be used without replacement of the typical focus ring is about 5 mm, the abrasion thickness to be used without replacement of the focus ring 103 according to the embodiment of the present invention is about 0.75 mm. The focus ring 103 can be used for a longer period than the typical focus ring as much as the thickness of about 0.25 mm and thus, a replacement cost can be reduced.

For instance, if the typical focus ring is used for a period in which the thickness of about 0.25 mm or greater is subjected to the abrasion, the plasma sheath is formed at an inner portion of the edge of the wafer. As a result, a tilting phenomenon may occur. However, in this embodiment of the present invention, although the focus ring 103 is used for a period in which the thickness of about 0.25 mm or greater is subjected to the abrasion, the change in the plasma sheath does not occur since the surface of the wafer 102 and the surface 103C of the focus ring 103 are positioned at the portion with the same height. Accordingly, the tilting phenomenon can be prevented.

Although the thickness of about 0.75 mm is secured as the maximum section where the focus ring 103 is used, the maximum range of the section where the focus ring 103 is used is set at a thickness of about 5 mm to better prevent the tilting phenomenon. Accordingly, in this embodiment of the present invention, the section where the focus ring 103 is used corresponds to a section ranging from about +0.25 mm to about −0.25 mm, (i.e., the section where the focus ring 103 extends upward as much as a thickness of about +0.25 mm from a reference value of zero, and downward as much as a thickness of about −0.25 mm from the reference value of zero as compared to the section where the typical focus ring is used. Accordingly, a lifetime of the focus ring 103 is substantially the same as that of the typical focus ring, but provides an improved effect in preventing the tilting phenomenon.

In this embodiment of the present invention, as shown in FIG. 4, a distance between the second region 103B of the focus ring 103 and the bottom surface of the edge of the wafer 102 is also decreased simultaneously with the extending of the surface 103C of the first region 103A upward. A surface of the second region 103B also extends upward as much as the height H1 extended upward to dispose the surface 103C of the focus ring 103 higher than the surface of the wafer 102. Thus, the distance between the second region 103B and the bottom surface of the edge of the wafer 102 can be reduced.

Since the distance between the second region 103B and the bottom surface of the edge of the wafer 102 is reduced, an amount of the polymers generated at the bottom surface of the edge of the wafer 102 can be reduced as much as the reduced distance between the second region 103B and the bottom surface of the edge of the wafer 102.

According to the plasma etching apparatus in this embodiment of the present invention, the surface 103C of the first region 103A surrounding the edge of the wafer 102 extends upward, and the distance between the bottom surface of the edge of the wafer 102 and the second region 103B is reduced. As a result, the change in the plasma sheath can be prevented.

When a target layer formed over a wafer, which is already moved inside a target chamber, is etched to form a pattern (e.g., a contact hole), the plasma etching apparatus shown in FIG. 4 is used. A post etch treatment is employed to increase an effect in removing the polymer. Through the post etch treatment, not only the polymers generated at the bottom surface of the wafer 102 but also the polymers generated on an entire surface of the focus ring 103 can be removed.

A recipe for the post etch treatment will be explained hereinafter. To perform the post etch treatment, the plasma processing chamber is maintained at a pressure of about 15 mTorr. A top power of about 1,000 Wt, and a bottom power of about 200 Wb are added to the plasma processing chamber. A mixture gas of oxygen (O₂), and argon (Ar) is used as an etch gas. O₂ has a flow rate of about 200 sccm, and Ar has a flow rate of about 100 sccm. The post etch treatment is performed for about 40 seconds.

If the post etch treatment is performed using the above explained recipe, the polymers generated after etching to form a contact hole can be clearly removed. The focus ring 103 is not subjected to the abrasion by the above explained recipe of the post etch treatment.

In more detail, during the post etch treatment according to this embodiment of the present invention, the pressure ranges from about 13.5 mTorr to about 16.5 mTorr. The top power ranges from about 900 Wt to about 1,100 Wt. The bottom power ranges from about 180 Wb to about 220 Wb. The flow rate of 02 ranges from about 180 sccm to about 220 sccm. The flow rate of Ar ranges from about 90 sccm to about 110 sccm. The post etch treatment can be performed for about 30 seconds to about 50 seconds.

According to this embodiment of the present invention, a structure of the focus ring is changed by extending upward the surface of the focus ring, and reducing the distance between the bottom surface of the edge of the wafer and the focus ring. As a result, the change in the plasma sheath can be minimized to prevent the tilting phenomenon at the edge of the wafer, and minimize the polymers generated at the bottom surface of the edge of the wafer. Since the post etch treatment is additionally performed, the unnecessary polymers can be clearly removed. A production cost can be prevented from increasing due to an unnecessary replacement of the focus ring which is an expendable component.

While the present invention has been described with respect to the specific embodiments, it will be apparent to those skilled in the art that various changes and modifications may be made without departing from the spirit and scope of the invention as defined in the following claims.

What is claimed is:

1. A plasma etching apparatus, comprising:
a plasma processing chamber;
an electro static chuck installed in the plasma processing chamber and providing a region where a wafer is to be placed; and
a focus ring surrounding an edge of the wafer at an edge portion of the electro static chuck and including:
a first region surrounding the edge of the wafer; and
a second region disposed under a bottom surface of the wafer, wherein a surface of the first region is disposed higher than that of the wafer.

2. The plasma etching apparatus of claim 1, wherein a surface of the second region extends upward as much as an increased height of the first region to reduce a distance between the bottom surface of the edge of the wafer and the second region.

3. The plasma etching apparatus of claim 2, wherein if a section where the focus ring is used is identified by H when the surface of the wafer and the surface of the first region are disposed at a portion with the same height, the surface of each of the first and second regions has a height increased as much as a half of the height H.

4. The plasma etching apparatus of claim 3, wherein the H ranges from about 0 mm to 5 mm and a portion corresponding to the increased height of the first region is about 0.25 mm.

5. The plasma etching apparatus of claim 4, wherein the section where the focus ring is used due to the increased height of the first region ranges from about +0.25 mm to −0.25 mm from the reference surface.

6. A plasma etching method, comprising:
moving a wafer where a target layer is formed to the inside of a chamber of a plasma etching apparatus comprising a focus ring;
etching the target layer inside the chamber to form a pattern; and
performing a post etch treatment on the wafer and the focus ring.

7. The plasma etching method of claim 6, wherein the post etch treatment comprises using a mixture gas including oxygen and argon.

8. The plasma etching method of claim 7, wherein a flow rate of the oxygen gas ranges from about 180 sccm to 220 sccm; and a flow rate of the argon gas ranges from about 90 sccm to 110 sccm.

9. The plasma etching method of claim 7, wherein the post etch treatment is performed for about 30 seconds to 50 seconds at a pressure ranging from about 13.5 mTorr to 16.5 mTorr, a top power ranging from about 900 W to 1,100 W, and a bottom power ranging from about 180 W to 220 W.

10. The plasma etching method of claim 6, wherein the focus ring of the plasma etching apparatus comprises:
a first region surrounding an edge of the wafer; and
a second region disposed under a bottom surface of an edge of the wafer,
wherein the first region has a surface disposed higher than the surface of the wafer.

11. The plasma etching method of claim 10, wherein a surface of the second region extends upward as much as an increased height of the first region to reduce a distance between a bottom surface of the edge of the wafer and the second region.

12. The plasma etching method of claim 6, wherein the pattern includes a hole-type pattern.
